(19) United States
(12) Patent Application Publication
(10) Pub. No.: US 2013/0147503 A1
(43) Pub. Date: Jun. 13, 2013

(54) Liquid Cooled Planer

(71) Applicants: Vinod Kamath, Raleigh, NC (US); Derek I. Schmidt, Raleigh, NC (US); Mark E. Steinke, Durham, NC (US); James S. Womble, Hillsborough, NC (US)

(72) Inventors: Vinod Kamath, Raleigh, NC (US); Derek I. Schmidt, Raleigh, NC (US); Mark E. Steinke, Durham, NC (US); James S. Womble, Hillsborough, NC (US)

(73) Assignee: INTERNATIONAL BUSINESS MACHINES CORPORATION, Armonk, NY (US)

(21) Appl. No.: 13/323,330

(22) Filed: Dec. 12, 2011

(51) Int. Cl. G01R 31/02; G06F 1/20

(52) U.S. Cl. 324/750.14; 361/679.53; 361/679.31; 361/679.47

(57) ABSTRACT

A liquid cooled planer including: one or more computing components mounted on the planer, wherein at least one or more of the computing components is liquid cooled; one or more conductive cooling components mounted on the planer; and one or more convective cooling components mounted on the planer, wherein the convective cooling components are removable from the planer without removing the conductive cooling components from the planer.

### BACKGROUND OF THE INVENTION

1. Field of the Invention

The field of the invention is data processing, or, more specifically, planers and liquid cooled servers.

2. Description Of Related Art

Modern computing systems are comprised of computing components that generate heat. In order to maintain ideal system performance and to avoid damaging the computing components, the components must be cooled. One way that modern computing systems can be cooled through the use of water cooling techniques in which heat generated by a computing component is transferred to a liquid that is subsequently expelled from the computing system, thereby removing heat from the computing system. Apparatus utilized to implement such water cooling techniques are often difficult to service and add complexity to the manufacturing process. Apparatus utilized to implement water cooling techniques can include cold plate that includes channels embedded within the cold plate for carrying water. As such, in order to perform testing operations of a computing system during the manufacturing process, a manufacturing facility will need a water source to provide water to the cold plate. Furthermore, when servicing such a computing system, the entire cold plate must be removed to service the water cooling components of the cooling plate, which can require special tools and a high degree of labor.

### SUMMARY OF THE INVENTION

A liquid cooled planer that includes: one or more computing components mounted on the planer, wherein at least one or more of the computing components is liquid cooled; one or more conductive cooling components mounted on the planer; and one or more convective cooling components mounted on the planer, wherein the convective cooling components are removable from the planer without removing the conductive cooling components from the planer.

The foregoing and other objects, features and advantages of the invention will be apparent from the following more particular descriptions of example embodiments of the invention as illustrated in the accompanying drawings wherein like reference numbers generally represent like parts of example embodiments of the invention.

### BRIEF DESCRIPTION OF THE DRAWINGS

FIG. 1 sets forth a block diagram of automated computing machinery comprising an example liquid cooled server according to embodiments of the present invention.

FIG. 2 sets forth a diagram of a planer according to embodiments of the present invention.

FIG. 3 sets forth a further diagram of a planer according to embodiments of the present invention.

FIG. 4 sets forth a further diagram of a planer according to embodiments of the present invention.

FIG. 5 sets forth a further diagram of a planer according to embodiments of the present invention.

FIG. 6 sets forth sets forth a further diagram of a planer according to embodiments of the present invention.

FIG. 7 sets forth a flow chart illustrating an example method of testing a liquid cooled server according to embodiments of the present invention.

### DETAILED DESCRIPTION OF EXAMPLE EMBODIMENTS

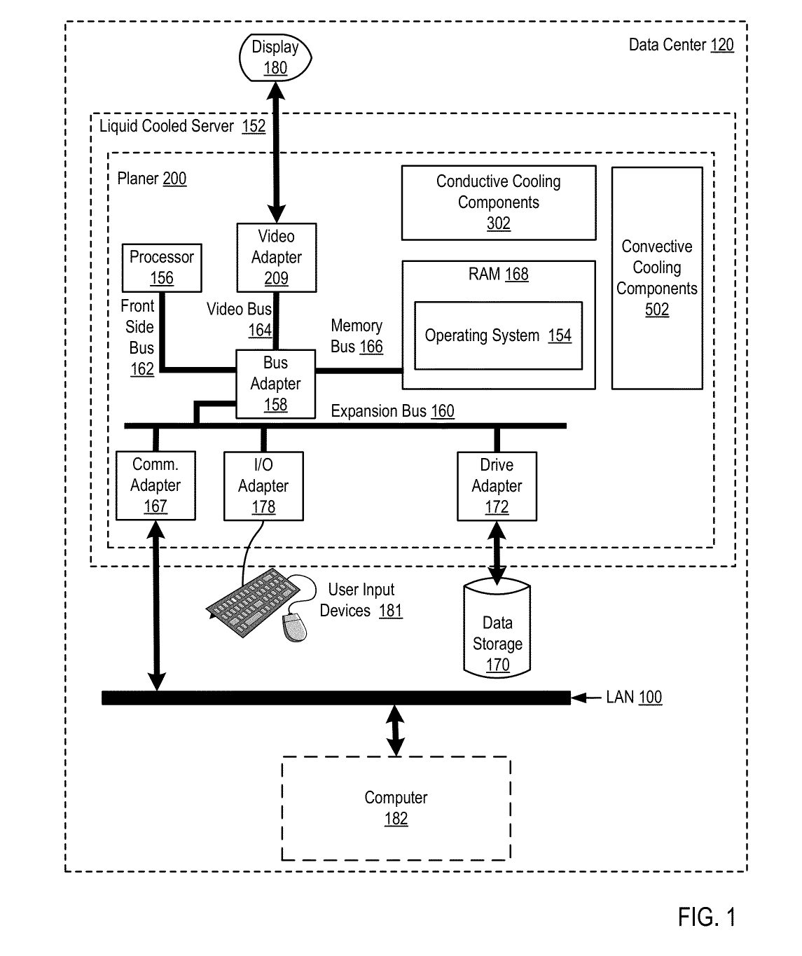

Example systems and apparatus in accordance with the present invention are described with reference to the accompanying drawings, beginning with FIG. 1.

FIG. 1 sets forth a block diagram of automated computing machinery comprising an example liquid cooled server (152) according to embodiments of the present invention. The liquid cooled server (152) of FIG. 1 includes at least one computer processor (156) or ‘CPU’ as well as random access memory (168) (‘RAM’) which is connected through a high speed memory bus (166) and bus adapter (158) to processor (156) and to other components of the liquid cooled server (152).

Stored in RAM (168) is an operating system (154). Operating systems used by liquid cooled servers according to embodiments of the present invention include UNIX™, Linux™, Microsoft XP™, AIX™, IBM's i5/OS™, and others as will occur to those of skill in the art. The operating system (154) in the example of FIG. 1 is shown in RAM (168), but many components of such software typically are stored in non-volatile memory also, such as, for example, on a disk drive (170).

The liquid cooled server (152) of FIG. 1 includes disk drive adapter (172) coupled through expansion bus (160) and bus adapter (158) to processor (156) and other components of the liquid cooled server (152). Disk drive adapter (172) connects non-volatile data storage to the liquid cooled server (152) in the form of disk drive (170). Disk drive adapters useful in liquid cooled servers according to embodiments of the present invention include Integrated Drive Electronics (‘IDE’) adapters, Small Computer System Interface (‘SCSI’) adapters, and others as will occur to those of skill in the art. Non-volatile computer memory also may be implemented for as an optical disk drive, electrically erasable programmable read-only memory (so-called ‘EEPROM’ or ‘Flash’ memory), RAM drives, and so on, as will occur to those of skill in the art.

The example liquid cooled server (152) of FIG. 1 includes one or more input/output (‘I/O’) adapters (178). I/O adapters implement user-oriented input/output through, for example, software drivers and computer hardware for controlling output to display devices such as computer display screens, as well as user input from user input devices (181) such as keyboards and mice. The example liquid cooled server (152) of FIG. 1 includes a video adapter (209), which is an example of an I/O adapter specially designed for graphic output to a display device (180) such as a display screen or computer monitor. Video adapter (209) is connected to processor (156) through a high speed video bus (164), bus adapter (158), and the front side bus (162), which is also a high speed bus.

The example liquid cooled server (152) of FIG. 1 includes a communications adapter (167) for data communications with other computers (182) and for data communications with a data communications network (100). Such data communications may be carried out serially through RS-232 connections, through external buses such as a Universal Serial Bus (‘USB’), through data communications networks such as IP data communications networks, and in other ways as will occur to those of skill in the art. Communications adapters implement the hardware level of data communications through which one computer sends data communications to another computer, directly or through a data communications network. Examples of communications adapters useful in liquid cooled servers according to embodiments of the present invention include modems for wired dial-up communications, Ethernet (IEEE 802.3) adapters for wired data communications network communications, and 802.11 adapters for wireless data communications network communications.

In the example of FIG. 1, many of the computing components described above reside on a planer (200). The planer (200) of FIG. 1 may be embodied, for example, as a printed circuit board (‘PCB’) configured to receive computing components such as computer memory, computer processors, and so on. In the example of FIG. 1 at least one or more of the computing components mounted on the planer (200) is liquid cooled. A computing component is liquid cooled in the sense that the computing component may be cooled using water cooling techniques. Cooling the computing components using water cooling techniques may be carried out, for example, by directly or indirectly connecting a water cooled mechanism such as a water pipe to the computing components. Heat generated by the computing components may therefore be transferred to the water cooled mechanism and passed to liquid that is flowing through the water cooled mechanism. In such an example, thermal heat is passed to the liquid and the liquid is subsequently expelled from the water cooled mechanism, such that heat generated by the computing components is also expelled from the water cooled mechanism. By continuing to introduce cool liquid into such a system and continuing to expel warmer liquid that has is carrying heat generated by the computing components, the computing components may be cooled as heat generated by such computing components is expelled from the system containing such computing components.

The planer (200) of FIG. 1 also includes conductive cooling components (302). In the example of FIG. 1, one or more conductive cooling components (302) are mounted on the planer (200). The conductive cooling components (302) of FIG. 1 are cooling components that are used to transfer heat generated by computing components mounted on the planer (200) away from the heat-generating computing components mounted on the planer (200). The conductive cooling components (302) may be embodied, for example, as a cold plate that transfers heat generated by computing components mounted on the planer (200) to a heat dissipating object such as a heat sink. The conductive cooling components (302) are ‘conductive’ in the sense that the conductive cooling components (302) transfers heat away from heat-generating computing components mounted on the planer (200) through physical contact with the heat-generating computing components or their mountings.

In the example of FIG. 1, the conductive cooling components (302) may be mounted on various parts of the planer (200), for example, such that the conductive cooling components (302) include both a front cooling rail and a back cooling rail that are mounted on opposing sides of the planer (200). The conductive cooling components (302) themselves do not have any channels through which liquids for liquid cooling can flow. The conductive cooling components (302), however, may include a support structure upon which liquid cooling components may be installed.

The planer (200) of FIG. 1 also includes convective cooling components (502). In the example of FIG. 1, one or more convective cooling components (502) are also mounted on the planer (200). In the example of FIG. 1, the convective cooling components (502) are cooling components that utilize water cooling techniques to cool computing components that are mounted on the planer (200). The convective cooling components (502) may utilize water cooling techniques to cool computing components that are mounted on the planer (200), for example, by passing cool water through pipes that make up the convective cooling components (502). Cool water may enter the convective cooling components (502) and pass through the convective cooling components (502). In such an example, the convective cooling components (502) may be directly or indirectly connected to heat-generating computing components mounted on the planer (200) such that heat from such heat-generating computing components is thermally transferred to the water that is passing through pipes that make up the convective cooling components (502). Heat from the heat-generating computing components may therefore be removed as the water can flow out of the pipes that make up the convective cooling components (502).

In the example of FIG. 1, the convective cooling components (502) are removable from the planer (200) without removing the conductive cooling components (302) from the planer (200). The convective cooling components (502) may be removable from the planer (200) without removing the conductive cooling components (302) from the planer (200), for example, by removeably mounting the convective cooling components (502) from the planer (200). For example, the convective cooling components (502) may be embodied as a water carrying pipe that is removeably attached to a conductive cooling component (302) embodied as a cold plate. In such an example, the water carry pipe may be removeably attached to the cold plate through the use of braces, brackets, or other physical elements such that detaching the water carry pipe from the cold plate only involves removing disengaging the water carrying pipe from the braces, brackets, or other physical elements.

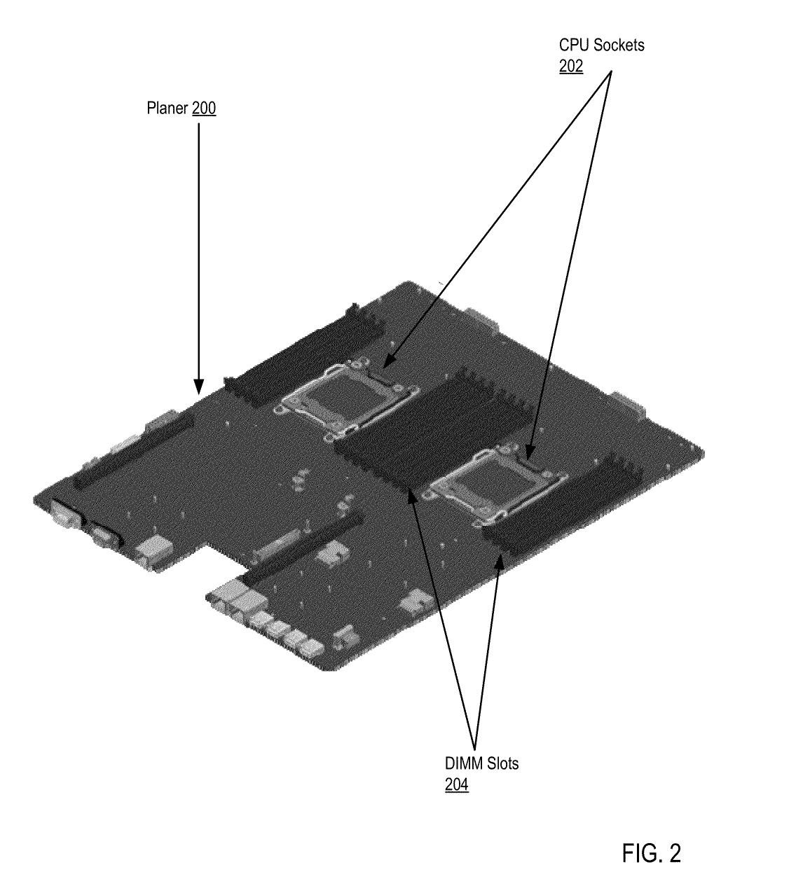

For further explanation, FIG. 2 sets forth a diagram of a planer (200) according to embodiments of the present invention. The planer (200) of FIG. 2 may be embodied, for example, as a printed circuit board (‘PCB’) configured to receive computing components such as computer memory, computer processors, and so on. The planer (200) of FIG. 2 may operate as a motherboard or other system board that includes a chipset that forms an interface between a front-side bus, memory, and peripheral busses, non-volatile memory, a clock signal generator, slots for expansion cards, power connectors, and so on.

In the example of FIG. 2, the planer (200) includes CPU sockets (202) that are each capable of receiving a computer processor. Such CPU sockets (202) may provide mechanical and electrical connections between a CPU that is mounted with the CPU socket (202) and the planer (200). The planer (200) of FIG. 2 also includes memory slots (204) that are each capable of receiving a computer memory component such as, for example, a dual in-line memory module (‘DIMM’), a single in-line memory module (‘SIMM’), and so on.

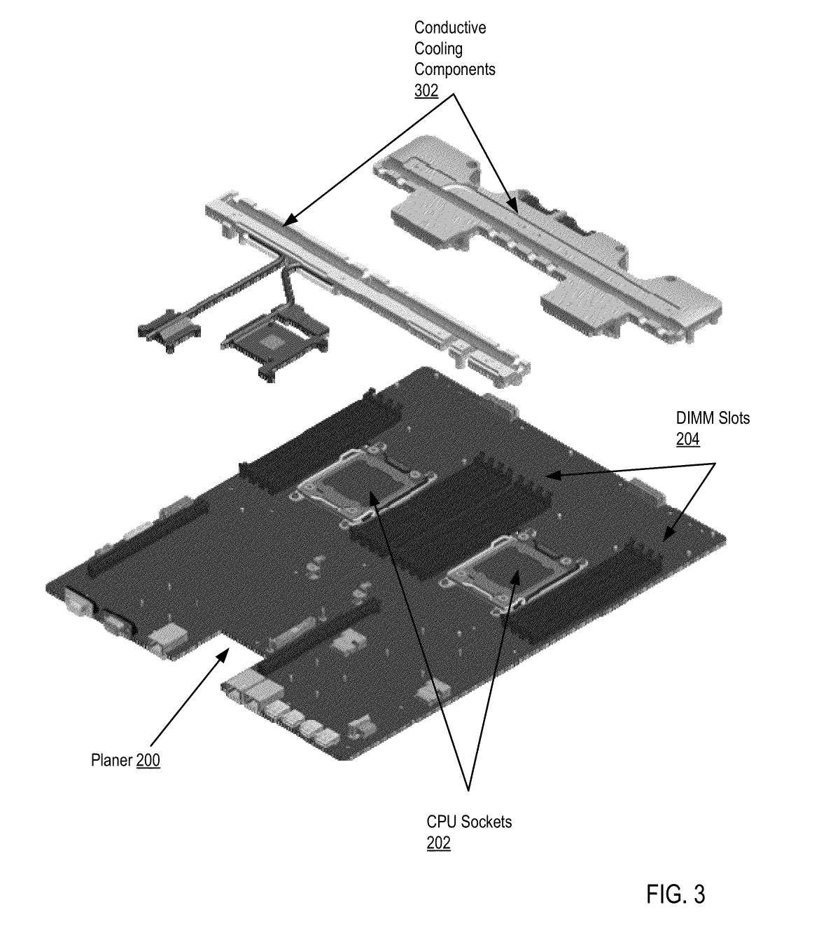

For further explanation, FIG. 3 sets forth a diagram of a planer (200) according to embodiments of the present invention. The conductive cooling components (302) of FIG. 3 are cooling components that are used to transfer heat generated by computing components mounted on the planer (200) away from the heat-generating computing components mounted on the planer (200). The conductive cooling components (302) may be embodied, for example, as a cold plate that transfers heat generated by computing components mounted on the planer (200) to a heat dissipating object such as a heat sink. The conductive cooling components (302) are ‘conductive’ in the sense that the conductive cooling components (302) transfers heat away from heat-generating computing components mounted on the planer (200) through physical contact with the heat-generating computing components or their mountings.

In the example of FIG. 3, the conductive cooling components (302) may be mounted on the planer (200). The conductive cooling components (302) may be mounted on various parts of the planer (200), for example, such that the conductive cooling components (302) include both a front cooling rail and a back cooling rail that are mounted on opposing sides of the planer (200). The conductive cooling components (302) themselves do not have any channels through which liquids for liquid cooling can flow. The conductive cooling components (302), however, may include a support structure upon which liquid cooling components may be installed.

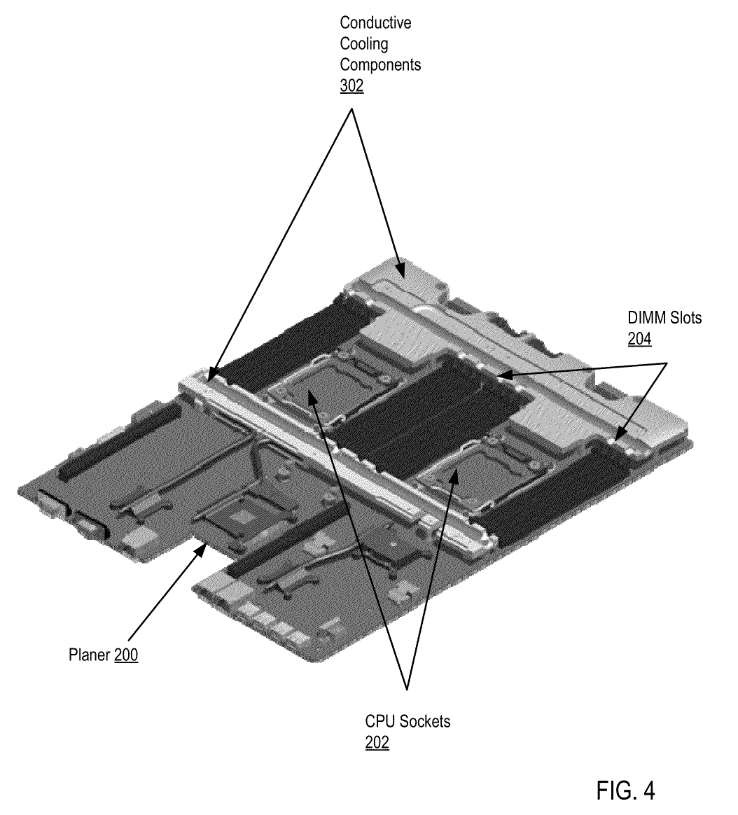

For further explanation, FIG. 4 sets forth a diagram of a planer (200) according to embodiments of the present invention. In the example of FIG. 4, the conductive cooling components (302) are mounted upon the planer (200), for example, through the use of connective elements such as hooks, latches, anchors, and so on that physically connect the conductive cooling components (302) to the planer (200). Although not shown in the example of FIG. 4, readers will appreciate that the conductive cooling components (302) may be coupled to a heat dissipating object such as a heat sink.

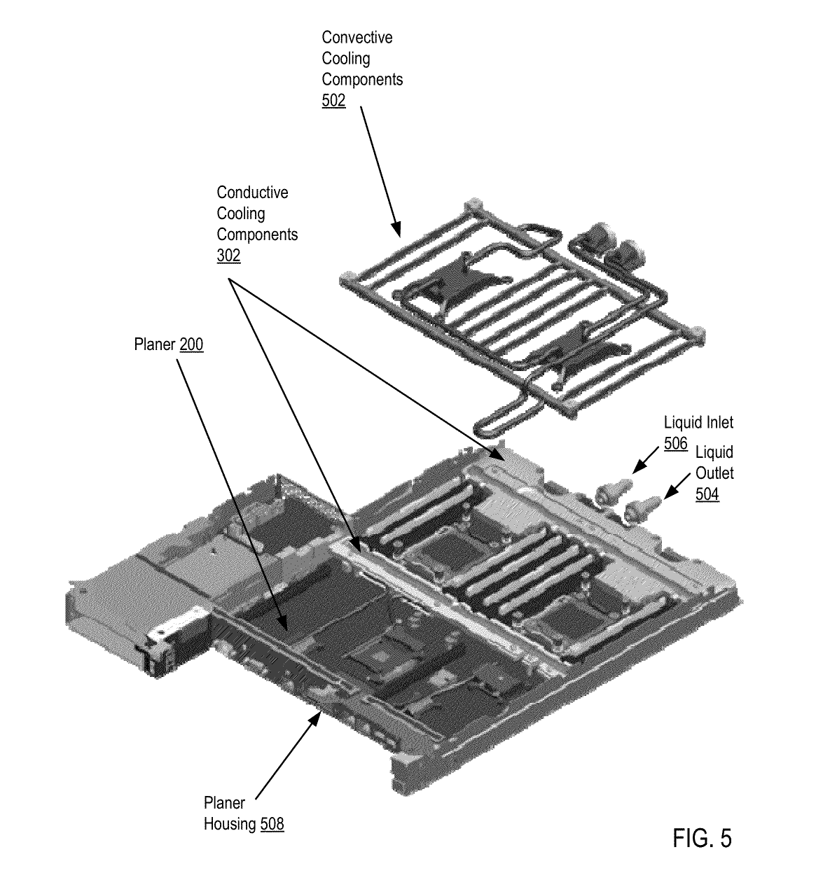

For further explanation, FIG. 5 sets forth a diagram of a planer (200) according to embodiments of the present invention. In the example of FIG. 5, the planer (200) is mounted within a planer housing (508). The planer housing (508) of FIG. 5 is an apparatus in which a planer (200) may be installed as part of a larger computing system. The planer housing (508) of FIG. 5 may be embodied, for example, as a server, a blade server, a general purpose computer, or other embodiments as will occur to those of skill in the art.

The example of FIG. 5 also includes convective cooling components (502). In the example of FIG. 5, the convective cooling components (502) are cooling components that utilize water cooling techniques to cool computing components that are mounted on the planer (200). The convective cooling components (502) may utilize water cooling techniques to cool computing components that are mounted on the planer (200), for example, by passing cool water through pipes that make up the convective cooling components (502). Cool water may enter the convective cooling components (502) and pass through the convective cooling components (502). In such an example, the convective cooling components (502) may be directly or indirectly connected to heat-generating computing components mounted on the planer (200) such that heat from such heat-generating computing components is thermally transferred to the water that is passing through pipes that make up the convective cooling components (502). Heat from the heat-generating computing components may therefore be removed as the water can flow out of the pipes that make up the convective cooling components (502).

In the example of FIG. 5, a liquid inlet (506) can be used to pass cool water or other cooling liquid into the convective cooling components (502). The liquid inlet (506) of FIG. 5 may be attached, for example, to a faucet or other water source capable of providing cooling liquid to the liquid inlet (506). In the example of FIG. 5, a liquid outlet (504) can also be used to pass cool water or other cooling liquid out of the convective cooling components (502). The liquid outlet (504) of FIG. 5 may be attached, for example, to a waste water system or other system capable of receiving cooling liquid from the convective cooling components (502).

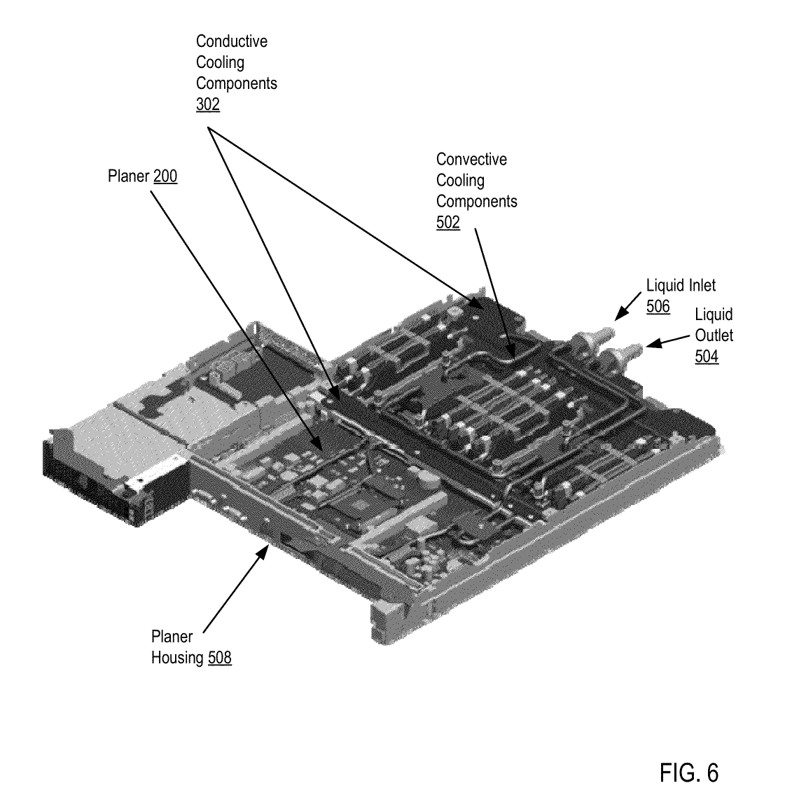

For further explanation, FIG. 6 sets forth a diagram of a planer (200) according to embodiments of the present invention. The example of FIG. 6 is similar to the example of FIG. 5. In the example of FIG. 6, however, the conductive cooling components (302) are shown as being mounted upon the planer (200). The example of FIG. 6 includes one or more computing components mounted on the planer (200). In the example of FIG. 6, the one or more computing components mounted on the planer (200) may be embodied, for example, as a computer processor, a DIMM, or other computing component as will occur to those of skill in the art.

In the example of FIG. 6 at least one or more of the computing components is liquid cooled. In the example of FIG. 6, at least one or more of the computing components is liquid cooled in the sense that the computing components may be cooled using water cooling techniques. Cooling the computing components using water cooling techniques may be carried out, for example, by directly or indirectly connecting a water cooled mechanism such as the convection cooling components (502) to the computing components. Heat generated by the computing components may therefore be transferred to the water cooled mechanism and passed to liquid that is flowing through the water cooled mechanism. In such an example, thermal heat is passed to the liquid and the liquid is subsequently expelled from the water cooled mechanism, such that heat generated by the computing components is also expelled from the water cooled mechanism. By continuing to introduce cool liquid into such a system and continuing to expel warmer liquid that has is carrying heat generated by the computing components, the computing components may be cooled as heat generated by such computing components is expelled from the system containing such computing components.

In the example of FIG. 6, one or more conductive cooling components (302) are mounted on the planer (200). The conductive cooling components (302) of FIG. 6 are cooling components that are used to transfer heat generated by computing components mounted on the planer (200) away from the heat-generating computing components mounted on the planer (200). The conductive cooling components (302) may be embodied, for example, as a cold plate that transfers heat generated by computing components mounted on the planer (200) to a heat dissipating object such as a heat sink. The conductive cooling components (302) are ‘conductive’ in the sense that the conductive cooling components (302) transfers heat away from heat-generating computing components mounted on the planer (200) through physical contact with the heat-generating computing components or their mountings.

In the example of FIG. 6, the conductive cooling components (302) may be mounted on various parts of the planer (200), for example, such that the conductive cooling components (302) include both a front cooling rail and a back cooling rail that are mounted on opposing sides of the planer (200). The conductive cooling components (302) themselves do not have any channels through which liquids for liquid cooling can flow. The conductive cooling components (302), however, may include a support structure upon which liquid cooling components may be installed.

In the example of FIG. 6, one or more convective cooling components (502) are also mounted on the planer (200). In the example of FIG. 6, the convective cooling components (502) are cooling components that utilize water cooling techniques to cool computing components that are mounted on the planer (200). The convective cooling components (502) may utilize water cooling techniques to cool computing components that are mounted on the planer (200), for example, by passing cool water through pipes that make up the convective cooling components (502). Cool water may enter the convective cooling components (502) and pass through the convective cooling components (502). In such an example, the convective cooling components (502) may be directly or indirectly connected to heat-generating computing components mounted on the planer (200) such that heat from such heat-generating computing components is thermally transferred to the water that is passing through pipes that make up the convective cooling components (502). Heat from the heat-generating computing components may therefore be removed as the water can flow out of the pipes that make up the convective cooling components (502).

In the example of FIG. 6, the convective cooling components (502) are removable from the planer (200) without removing the conductive cooling components (302) from the planer (200). The convective cooling components (502) may be removable from the planer (200) without removing the conductive cooling components (302) from the planer (200), for example, by removeably mounting the convective cooling components (502) from the planer (200). For example, the convective cooling components (502) may be embodied as a water carrying pipe that is removeably attached to a conductive cooling component (302) embodied as a cold plate. In such an example, the water carry pipe may be removeably attached to the cold plate through the use of braces, brackets, or other physical elements such that detaching the water carry pipe from the cold plate only involves removing disengaging the water carrying pipe from the braces, brackets, or other physical elements.

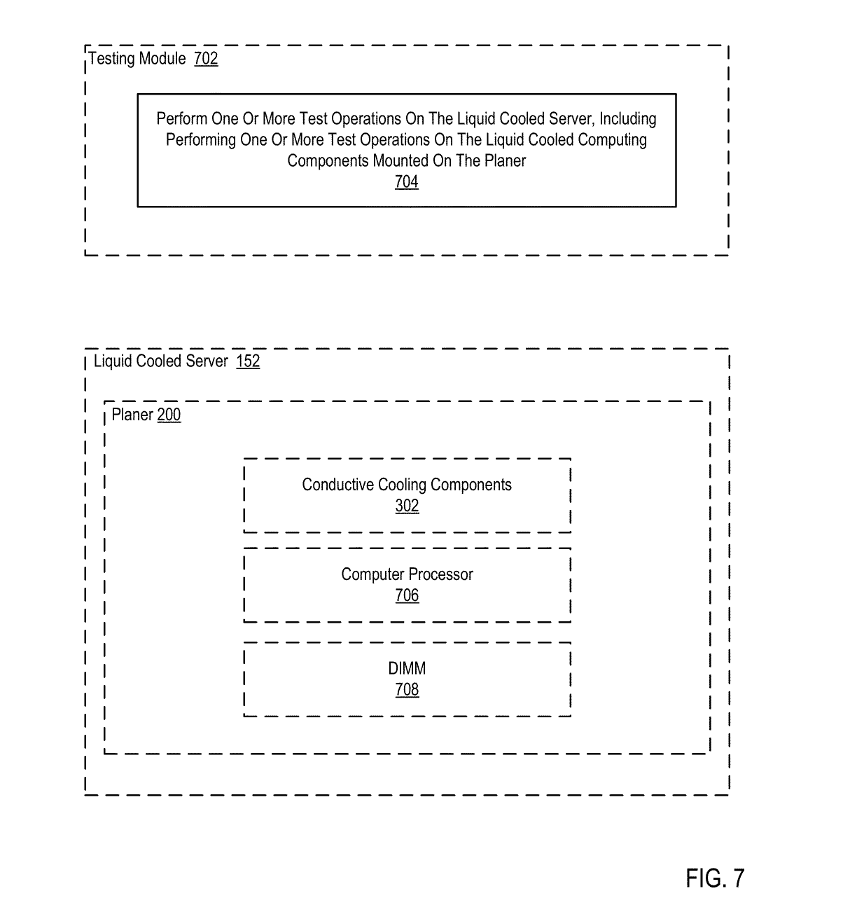

For further explanation, FIG. 7 sets forth a flow chart illustrating an example method of testing a liquid cooled server (152) according to embodiments of the present invention. The liquid cooled server of FIG. 7 includes a planer (200) that includes one or more liquid cooled computing components as described above with reference to FIG. 1-6. In the example method of FIG. 7, the one or more liquid cooled computing components can include a computer processor (706) and a DIMM (708).

The planer (200) of FIG. 7 includes one or more conductive computing components (302). The conductive cooling components (302) of FIG. 7 are cooling components that are used to transfer heat generated by computing components mounted on the planer (200) away from the heat-generating computing components mounted on the planer (200). The conductive cooling components (302) may be embodied, for example, as a cold plate that transfers heat generated by computing components mounted on the planer (200) to a heat dissipating object such as a heat sink. The conductive cooling components (302) are ‘conductive’ in the sense that the conductive cooling components (302) transfers heat away from heat-generating computing components mounted on the planer (200) through physical contact with the heat-generating computing components or their mountings.

The planer (200) of FIG. 7 is configured to support one or more convective cooling components. In the example of FIG. 7, convective cooling components are cooling components that utilize water cooling techniques to cool computing components that are mounted on the planer (200). The convective cooling components may utilize water cooling techniques to cool computing components that are mounted on the planer (200), for example, by passing cool water through pipes that make up the convective cooling components. Cool water may enter the convective cooling components and pass through the convective cooling components. In such an example, the convective cooling components may be directly or indirectly connected to heat-generating computing components mounted on the planer (200) such that heat from such heat-generating computing components is thermally transferred to the water that is passing through pipes that make up the convective cooling components. Heat from the heat-generating computing components may therefore be removed as the water can flow out of the pipes that make up the convective cooling components. In the example method of FIG. 7, however, no convective computing components are mounted on the planer (200) during performance of the one or more test operations.

The example method of FIG. 7 includes performing (704), by a testing module (702), one or more test operations on the liquid cooled server (152). The testing module (702) of FIG. 7 may be embodied as a module of computer program instructions that, when executed, perform test operations on computing components. Such test operations may ensure that a computing component is capable of receiving power, capable of communicating over a data communications channel such as a bus, and so on. Test operations may be useful during the manufacturing process of a liquid cooled server (152) as the test operations very that the physical components of the liquid cooled server (152) are operational.

In the example method of FIG. 7, performing (704) one or more test operations on the liquid cooled server (152) includes performing one or more test operations on the liquid cooled computing components mounted on the planer (200). Such test operations verify that each the liquid cooled computing components mounted on the planer (200) is operational. Such test operations are useful in discovering computing components that are defective, improperly installed, and so on.

In the example method of FIG. 7, the test operations typically place a lighter workload on a liquid cooled server (152) and the computing components therein than is experienced during actual operation of the liquid cooled server (152) and the computing components therein when the liquid cooled server (152) is deployed. As such, the amount of heat generated by the computing components is less than the amount of heat generated when the liquid cooled server (152) is deployed. Because the amount of heat generated by the computing components is less than the amount of heat generated when the liquid cooled server (152) is deployed, the conductive cooling components (302) alone can be sufficient to properly cool the computing components. As such, in the method of FIG. 7, no convective cooling components are mounted on the planer (200) when testing the liquid cooled server (152). Because no convective cooling components are mounted on the planer (200) when testing the liquid cooled server (152), the process of manufacturing and testing the liquid cooled server (152) can be simplified as a water source is not required in the manufacturing and testing facility to provide water to convective cooling components that will ultimately be mounted on the planer (200) when the liquid cooled server (152) is deployed.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described above with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A liquid cooled planer comprising:
one or more computing components mounted on the planer, wherein at least one or more of the computing components is liquid cooled;
one or more conductive cooling components mounted on the planer; and
one or more convective cooling components mounted on the planer, wherein the convective cooling components are removable from the planer without removing the conductive cooling components from the planer.

2. The liquid cooled planer of claim 1 wherein the one or more computing components includes a computer processor.

3. The liquid cooled planer of claim 1 wherein the one or more computing components includes a dual in-line memory module (‘DIMM’).

4. The liquid cooled planer of claim 1 wherein the one or more conductive cooling components mounted on the planer includes a cold plate.

5. The liquid cooled planer of claim 1 wherein the one or more convective cooling components mounted on the planer includes a water carrying pipe.

6. The liquid cooled planer of claim 5 wherein the water carrying pipe is removeably attached to a cold plate such that the water carrying pipe can be detached from the cold plate without removing the cold plate from the planer.

7. A liquid cooled server, the liquid cooled server including a computer processor, a computer memory operatively coupled to the computer processor, and a liquid cooled planer comprising:
one or more computing components mounted on the planer, wherein at least one or more of the computing components is liquid cooled;
one or more conductive cooling components mounted on the planer; and
one or more convective cooling components mounted on the planer, wherein the convective cooling components are removable from the planer without removing the conductive cooling components from the planer.

8. The liquid cooled server of claim 7 wherein the one or more computing components includes a dual in-line memory module (‘DIMM’).

9. The liquid cooled server of claim 7 wherein the one or more conductive cooling components mounted on the planer includes a cold plate.

10. The liquid cooled server of claim 7 wherein the one or more convective cooling components mounted on the planer includes a water carrying pipe.

11. The liquid cooled server of claim 7 wherein the water carrying pipe is removeably attached to a cold plate such that the water carrying pipe can be detached from the cold plate without removing the cold plate from the planer.

12. A method of testing a liquid cooled server, the liquid cooled server including a planer that includes one or more liquid cooled computing components and one or more conductive cooling components mounted on the planer, the method comprising:
performing, by a testing module, one or more test operations on the liquid cooled server, including performing one or more test operations on the liquid cooled computing components mounted on the planer, wherein the planer is configured to support one or more convective cooling components and wherein no convective cooling component is mounted on the planer during performance of the one or more test operations.

13. The method of claim 1 wherein the one or more conductive cooling components are configured to remove heat during execution of the test operations on the liquid cooled computing components mounted on the planer.

14. The method of claim 1 wherein the one or more conductive cooling components mounted on the planer includes a cold plate.

15. The method of claim 1 wherein the one or more computing components includes a computer processor.

16. The method of claim 1 wherein the one or more computing components includes a dual in-line memory module (‘DIMM’).
